(19) United States
(12) Patent Application Publication
(10) Pub. No.: US 2016/0218619 A1
(43) Pub. Date: Jul. 28, 2016

(54) DATA PIN REFERENCE VOLTAGE GENERATION CIRCUIT AND SEMICONDUCTOR DEVICE INCLUDING THE SAME

(71) Applicant: SK hynix Inc., Icheon-si (KR)

(72) Inventor: Sangkug LYM, Icheon-si Gyeonggi-do (KR)

(21) Appl. No.: 14/730,594

(22) Filed: Jun. 4, 2015

(30) Foreign Application Priority Data
Jan. 27, 2015 (KR) 10-2015-0012531

(51) Int. Cl. H02M 3/158; G11C 5/14

(52) U.S. Cl. CPC H02M 3/158; G11C 5/147

(57) ABSTRACT

A data pin reference voltage generation circuit may include a voltage difference storage block configured to accumulatively store a difference between an input signal received through a data pin and a reference voltage for a preset time. The data pin reference voltage generation circuit may include a code generator configured to generate a voltage generation code based on the voltage difference stored in the voltage difference storage block. The data pin reference voltage generation circuit may include a reference voltage generator configured to generate the reference voltage based on the voltage generation code.

### CROSS-REFERENCES TO RELATED APPLICATION

The present application claims priority under 35 U.S.C. §119(a) to Korean application number 10-2015-0012531, filed on Jan. 27, 2015, in the Korean Intellectual Property Office, which is incorporated herein by reference in its entirety.

### BACKGROUND

1. Technical Field

Various embodiments generally relate to a data pin reference voltage generation circuit and a semiconductor device including the same. More particularly, various embodiments relate to a data pin reference voltage generation circuit including a means for generating different reference voltages for data pins. Various embodiments relate to a semiconductor device including the data pin reference voltage generation circuit including the means for generating the different reference voltages for the data pins.

2. Related Art

In a semiconductor chip, pluralities of data pins are provided for inputting and outputting data to and from the semiconductor chip. In general, data may be identified by a binary value of ‘1’ or ‘0’. Identification of data may be carried out in such a manner that a data signal provided to a data pin and a reference voltage are compared. The data signal is determined as having the value of ‘1’ when the level of the data signal is higher than the reference voltage and as having the value of ‘0’ when the level of the data signal is lower than the reference voltage (or vice versa).

In this regard, paths through which data signals are transferred may be different as the plurality of data pins are formed at different positions. Data signals with different properties may be inputted due to the presence of other elements around the data pins. Therefore, in the case where data are identified based on the same reference voltage with respect to the plurality of data pins, the reliability of identifying data may be degraded.

### SUMMARY

In an embodiment, a data pin reference voltage generation circuit may include a voltage difference storage block configured to accumulatively store a difference between an input signal received through a data pin and a reference voltage for a preset time. The data pin reference voltage generation circuit may include a code generator configured to generate a voltage generation code based on the voltage difference stored in the voltage difference storage block. The data pin reference voltage generation circuit may include a reference voltage generator configured to generate the reference voltage based on the voltage generation code.

In an embodiment, a semiconductor device may include a memory controller configured to provide a training waveform through at least one data pin, along with an amplification enable signal. The semiconductor device may include at least one data pin reference voltage generation circuit configured to accumulatively store a difference between the training waveform and a reference voltage in response to the amplification enable signal, and generate the reference voltage through updating.

### BRIEF DESCRIPTION OF THE DRAWINGS

FIG. 1 is a block diagram illustrating a representation of an example of a data pin reference voltage generation circuit in accordance with an embodiment.

FIGS. 2 and 3 are diagrams illustrating representations of examples of the voltage difference storage block illustrated in FIG. 1.

FIG. 4 illustrates representations of examples of waveform diagrams to assist in the explanation of operations of the data pin reference voltage generation circuit in accordance with an embodiment.

FIG. 5 is a circuit diagram illustrating a representation of an example of the input buffer included in the data pin reference voltage generation circuit of FIG. 1.

FIG. 6 is a block diagram schematically illustrating a representation of an example of the configuration of a semiconductor system in accordance with an embodiment.

FIG. 7 is a block diagram illustrating a representation of an example of the configuration of an electronic device in accordance with an embodiment.

### DETAILED DESCRIPTION

Hereinafter, a data pin reference voltage generation circuit and a semiconductor device including the same may be described below with reference to the accompanying drawings through various examples of embodiments.

Various embodiments may be directed to a semiconductor device which may differently generate reference voltages for data pins, thereby improving reliability in the example of receiving data signals through a plurality of data pins.

Various embodiments may be directed to a data pin reference voltage generation circuit which may generate an updated reference voltage through a simple method of comparing a training waveform and a reference voltage, and storing a voltage difference when generating a reference voltage for a data pin.

In a data pin reference voltage generation circuit and a semiconductor device including the same according to an embodiment, since a reference voltage may be controlled for each data pin, an input signal received through each data pin may be precisely identified.

In a data pin reference voltage generation circuit and a semiconductor device including the same according to an embodiment, because a reference voltage for each data pin may be controlled through a simple configuration, a substantial increase in size may not be caused even though the reference voltage is controlled for each data pin.

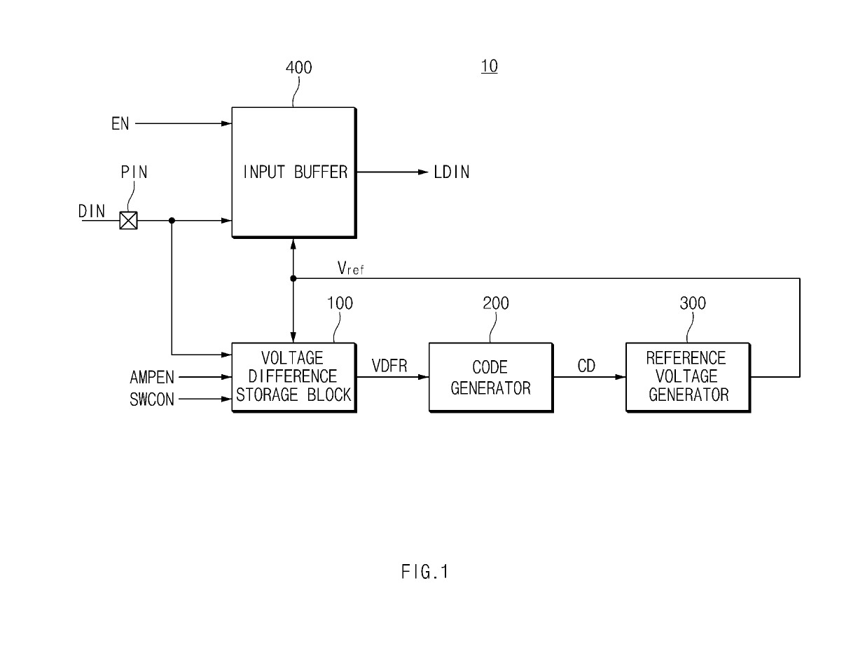

FIG. 1 is a block diagram illustrating a representation of an example of a data pin reference voltage generation circuit in accordance with an embodiment.

Referring to FIG. 1, a data pin reference voltage generation circuit 10 may include a voltage difference storage block 100, a code generator 200, and a reference voltage generator 300.

The voltage difference storage block 100 may accumulatively store the difference between an input signal DIN received through a data pin PIN for a preset time and a reference voltage V_{ref}. The voltage difference storage block 100 may accumulatively store the difference between the input signal DIN received through the data pin PIN for the preset time and the reference voltage V_{ref} in response to an amplification enable signal AMPEN. The voltage difference storage block 100 may provide the difference between both voltages that are stored after the preset time passes, to the code generator 200, as a voltage difference VDFR.

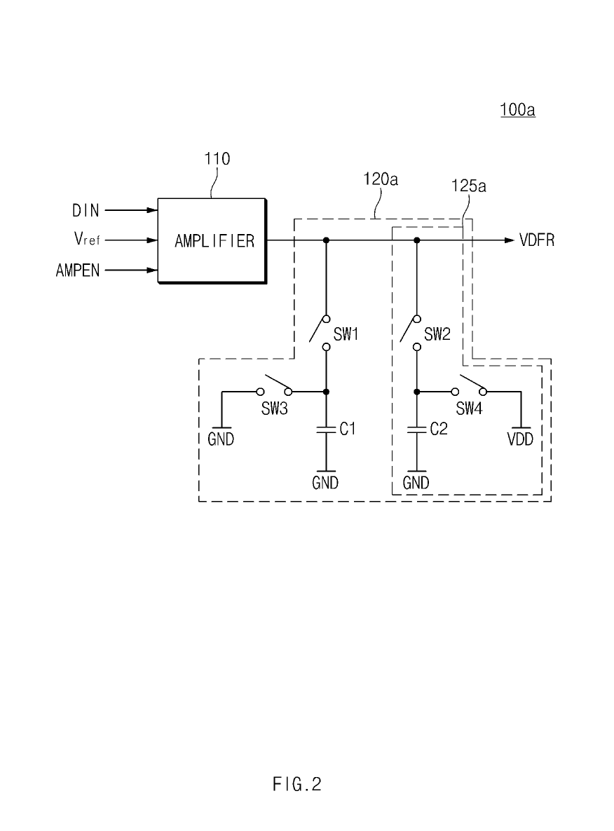

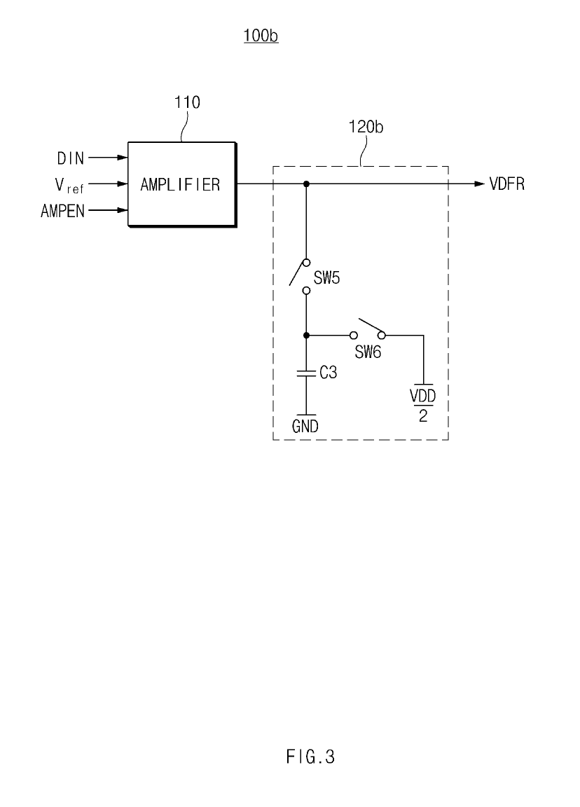

According to an embodiment, the voltage difference storage block 100 may store the difference between the input signal DIN and the reference voltage V_{ref}, in the form of charges, for the preset time in response to a switching control signal SWCON. The configuration of the voltage difference storage block 100 will be described with reference to FIGS. 2 and 3.

The amplification enable signal AMPEN may be enabled in a training operation process. Training may be performed in an initial state after power is applied to the data pin reference voltage generation circuit 10.

The code generator 200 may generate a voltage generation code CD based on the voltage difference VDFR. The code generator 200 may include an analog-to-digital converter. The analog-to-digital converter converts, analog-to-digital, the voltage difference VDFR provided from the voltage difference storage block 100.

The reference voltage generator 300 may generate the reference voltage V_{ref} based on the voltage generation code CD. Since the reference voltage V_{ref} is controlled for the input signal DIN received from each data pin PIN, a plurality of data pins PIN provided in a semiconductor device may have different values of the reference voltage V_{ref}.

In the data pin reference voltage generation circuit 10 in accordance with an embodiment, since the property of each data pin PIN may be reflected on the reference voltage V_{ref}, a data margin for the input signal DIN may be increased, and as a result, data input/output precision may be improved.

According to an embodiment, the data pin reference voltage generation circuit 10 may further include an input buffer 400. The input buffer 400 may operate in response to an enable signal EN. For example, the enable signal EN may be enabled in a normal operation after training is completed as the amplification enable signal AMPEN is enabled.

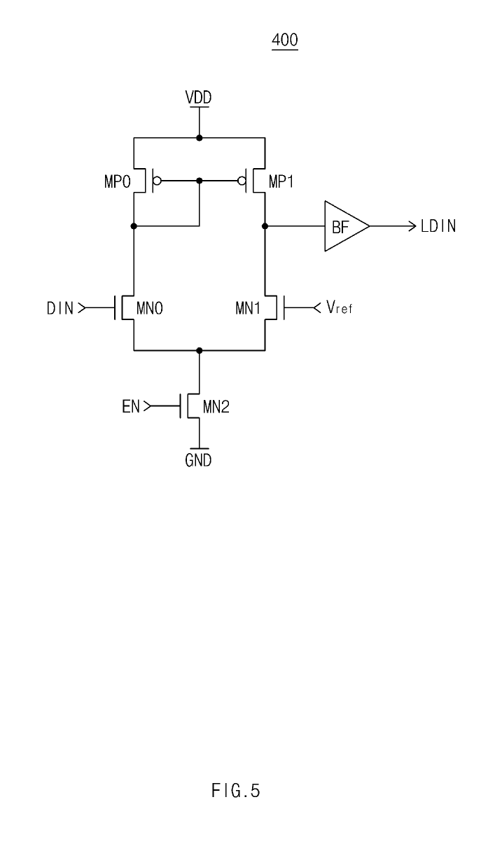

The input buffer 400 may receive the input signal DIN from the data pin PIN, compare the input signal DIN with the training-completed reference voltage V_{ref}, and provide a latched output signal LDIN. For example, the input buffer 400 may amplify the difference between the input signal DIN and the reference voltage V_{ref}, pass the amplified difference through a buffer, and provide the latched output signal LDIN with a certain logic state. The configuration of the input buffer 400 will be described later with reference to FIG. 5.

FIG. 2 is a diagram illustrating a representation of an example of the voltage difference storage block illustrated in FIG. 1.

Referring to FIG. 2, a voltage difference storage block 100a may include an amplifier 110 and a charge storage unit 120a.

The amplifier 110 amplifies the difference between the input signal DIN and the reference voltage V_{ref}. The amplifier 110 may amplify the difference between the input signal DIN and the reference voltage V_{ref} in response to the amplification enable signal AMPEN, and may provide the amplified difference to the charge storage unit 120a.

The charge storage unit 120a may include a first switch SW1 and a first capacitor C1. The first switch SW1 and the first capacitor C1 may be coupled with an output terminal of the amplifier 110. The first switch SW1 couples the output terminal of the amplifier 110 and the first capacitor C1 in response to the amplification enable signal AMPEN such that the difference between the input signal DIN and the reference voltage V_{ref} may be stored as charges.

According to an embodiment, the charge storage unit 120a may further include a third switch SW3. The third switch SW3 may selectively couple a terminal between the first switch SW1 and the first capacitor C1 with a ground voltage GND. The third switch SW3 may function to initialize the charges of the first capacitor C1 after a charge variation occurs due to the storage of the difference between the input signal DIN and the reference voltage V_{ref} in the first capacitor C1.

In an embodiment, signals provided for coupling of switches may be included in the switching control signal SWCON illustrated in FIG. 1.

The first capacitor C1 may be coupled between the first switch SW1 and the ground voltage GND. The first capacitor C1 may store the voltage difference between the input signal DIN and the reference voltage V_{ref} in the form of charges for the preset time, for example, a time during which the amplification enable signal AMPEN is enabled.

According to an embodiment, the first capacitor C1 may be provided with a value corresponding to the default value of the reference voltage V_{ref} as a charge storing initial value. For example, the charge storing initial value may be a value corresponding to the ½ value of a power supply voltage VDD. As the first capacitor C1 is provided with the charge storing initial value, the value stored in the first capacitor C1 after the preset time passes may correspond to a value with which the reference voltage V_{ref} should be actually updated.

For example, the reference voltage V_{ref} generally has a value approximate to a value corresponding to the ½ value of the power supply voltage VDD. While it may be necessary to control the value of the reference voltage V_{ref} since the property of the input signal DIN is different with respect to each data pin PIN, the value provided from the amplifier 110 during training may be the value corresponding to the difference between the input signal DIN and the reference voltage V_{ref}, and the reference voltage V_{ref} may be initially set, at default, as the value corresponding to ½ of the power supply voltage VDD.

In the example where the value corresponding to ½ of the power supply voltage VDD is stored in advance as the charge storing initial value for the first capacitor C1, the voltage difference VDFR stored after the preset time passes may correspond to the analog value of the training-completed reference voltage V_{ref}.

In an embodiment illustrated in FIG. 2, an initialization section 125a may be constructed to include a second switch SW2, a second capacitor C2, and a fourth switch SW4.

The second switch SW2 and the fourth switch SW4 may, for example, operate in response to the switching control signal SWCON illustrated in FIG. 1.

Before training is started, the fourth switch SW4 may be turned on, and the power supply voltage VDD is stored in the second capacitor C2. The second switch SW2 is in a turned-off state. Also, at this point in time, the third switch SW3 coupled between one end of the first capacitor C1 and the ground voltage GND is turned on, and the first capacitor C1 is in a state in which no charges are stored therein.

Thereafter, the third switch SW3 and the fourth switch SW4 may be turned off, and the first switch SW1 and the second switch SW2 are turned on, by which charge sharing between the first capacitor C1 and the second capacitor C2 is implemented. According to an embodiment, the first capacitor C1 and the second capacitor C2 have the same capacitance, and the same amount of charges is provided to the two capacitors C1 and C2. As a result, as charges corresponding to the ½ value of the power supply voltage VDD are stored in the first capacitor C1 and the second capacitor C2, the charge storing initial value is set.

In comparison with the first capacitor C1 which stores the difference between the input signal DIN and the reference voltage V_{ref}, the second capacitor C2, which is disposed to provide the charge storing initial value, may be referred to as an auxiliary capacitor.

Thereafter, the second switch SW2 and the fourth switch SW4 included in the initialization section 125a may be turned off in a training process.

The value of the charges accumulatively stored in the first capacitor C1 while the amplification enable signal AMPEN is enabled may be provided to the code generator 200 by complementarily responding to the amplification enable signal AMPEN.

FIG. 3 is a diagram illustrating a representation of an example of the voltage difference storage block illustrated in FIG. 1.

Referring to FIG. 3, a voltage different storage block 100b may include an amplifier 110 and a charge storage unit 120b. Since the amplifier 110 is substantially the same as the amplifier 110 of FIG. 2, detailed descriptions thereof will be omitted.

When compared to the voltage different storage block 100a of FIG. 2, the voltage different storage block 100b of FIG. 3 is different in that the voltage different storage block 100b includes a voltage source providing ½ VDD corresponding to the ½ value of a power supply voltage VDD.

The charge storage unit 120b may include a fifth switch SW5 and a third capacitor C3. The fifth switch SW5 and the third capacitor C3 may be coupled with an output terminal of the amplifier 110. The third capacitor C3 may be coupled between one end of the fifth switch SW5 and a ground voltage GND. A sixth switch SW6 may be disposed between the voltage source corresponding to an initialization section and one end of the third capacitor C3.

The fifth switch SW5 and the sixth switch SW6 included in the charge storage unit 120b of FIG. 3 may operate in response to the switching control signal SWCON of FIG. 1.

Operations of the charge storage unit 120b are as follows. Before training is started, the sixth switch SW6 may be turned on, and a charge storing initial value corresponding to ½ of the power supply voltage VDD (i.e., VDD/2) is set in the third capacitor C3. At this point in time, the fifth switch SW5 may be turned off.

Thereafter, as the sixth switch SW6 is turned off and the fifth switch SW5 is turned on, the difference between the input signal DIN and the reference voltage V_{ref} that is provided from the amplifier 110 is stored in the third capacitor C3. A signal controlling the turn-on of the fifth switch SW5 may correspond to the amplification enable signal AMPEN.

As a result, the charge storage unit 120b of FIG. 3 may perform substantially the same operations in a training process as the charge storage unit 120a of FIG. 2 except that the voltage source is disposed to provide the charge storing initial value.

The value of the charges accumulatively stored in the third capacitor C3 while the amplification enable signal AMPEN is enabled may be provided to the code generator 200 as the stored voltage difference VDFR by complementarily responding to the amplification enable signal AMPEN.

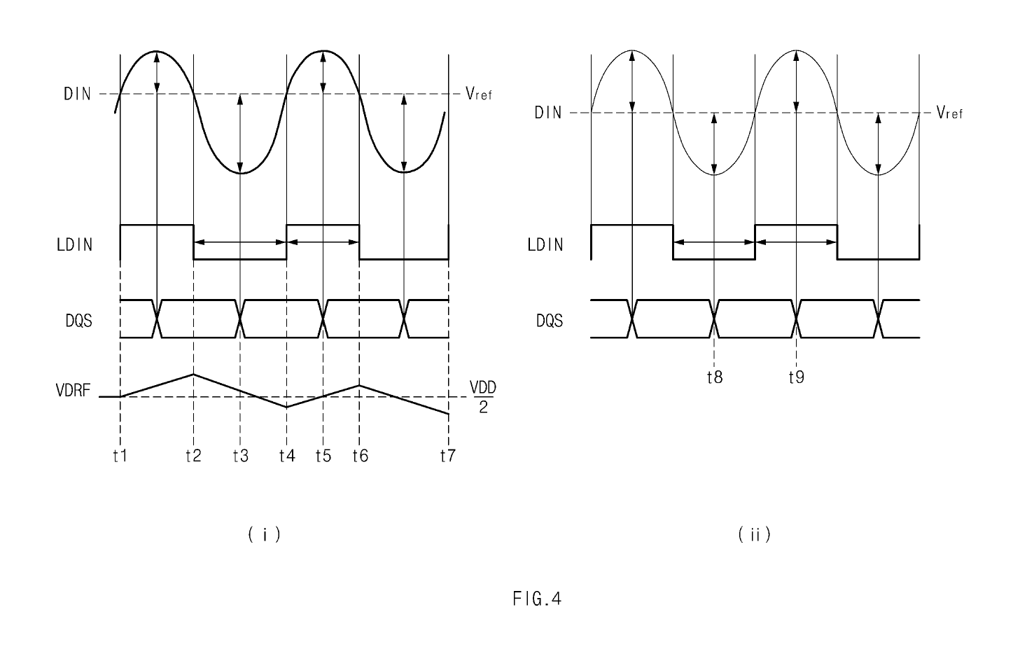

FIG. 4 illustrates representations of examples of waveform diagrams to assist in the explanation of operations of the data pin reference voltage generation circuit in accordance with an embodiment.

(i) illustrated on the left side of FIG. 4 illustrates waveforms to assist in the explanation of a period during which the reference voltage V_{ref} is trained. (ii) illustrated on the right side of FIG. 4 illustrates waveforms to assist in the explanation of a period after the reference voltage V_{ref} is trained and updated.

The input signal DIN may be provided through the data pin PIN during the training operation. In the present embodiment, the reference voltage V_{ref} may be controlled according to the voltage difference accumulatively stored by comparing the input signal DIN and the reference voltage V_{ref}. Thus, the waveform provided as the input signal DIN during the training operation may be provided as a waveform of which integral sum is ‘0’ when taking the reference voltage V_{ref} as a reference, that is, an origin. Herein, the reference voltage V_{ref} may correspond to a reference voltage to update, that is, a reference voltage of an ideal example.

A reference time for the integral sum may be the preset time during which charges are accumulatively stored in the voltage difference storage block 100, for example, a time during which the amplification enable signal AMPEN is enabled. For example, the preset time may be from t1 to t7.

While, in the present embodiment, a sine wave with respect to the reference voltage V_{ref} is exemplarily illustrated as the input signal DIN provided during the training, it is to be noted that a training waveform provided as the input signal DIN is not limited to such a sine wave.

At the time t1 as an initial time, it may be seen that, as described above, the voltage difference VDRF stored in the capacitor of the voltage difference storage block 100 is set as a charge storing initial value, that is, a value corresponding to ½ of the power supply voltage VDD.

From the time t1, the amplification enable signal AMPEN is enabled. During the period from the time t1 to the time t2, since the input signal DIN is higher than the reference voltage V_{ref}, by referring to the voltage difference VDRF corresponding to the amount of the charges stored in the charge storage unit 120a or 120b, it may be seen that charges are stored in the capacitor and the voltage difference VDRF is increased to be higher than the value corresponding to ½ of the power supply voltage VDD.

Also, during this period, since the input signal DIN is higher than the reference voltage V_{ref}, the latched output signal LDIN provided through the input buffer 400 may correspond to a ‘high’ state.

During the period from the time t2 to the time t4, since the input signal DIN is lower than the reference voltage V_{ref}, the charges stored in the charge storage unit 120a or 120b gradually decrease, and, after the time t3, the voltage difference VDRF corresponding to the amount of the charges stored in the charge storage unit 120a or 120b is decreased to be lower than the value corresponding to ½ of the power supply voltage VDD.

During the period from the time t4 to the time t6, since the input signal DIN is higher than the reference voltage V_{ref}, the amount of the charges stored in the charge storage unit 120a or 120b increases again.

It may be seen that, before the training operation, the reference voltage V_{ref} is lopsided upward from the center of the input signal DIN. Due to such a characteristic, a period during which the latched output signal LDIN is a ‘low’ state (the period from the time t2 to the time t4) is longer than a period during which the latched output signal LDIN is the ‘high’ state (the period from the time t4 to the time t6).

In the semiconductor device, a final data value is checked by sampling the latched output signal LDIN by a data strobe signal DQS. The latched output signal LDIN may be identified as a data value in response to the data strobe signal DQS at the time t3 and the time t5.

In this regard, as described above, if a period in which the latched output signal LDIN is the logic ‘low’ state is relatively long, with the cycle of the input signal DIN determined to be constant, a time for sampling the logic ‘high’ state, that is, a data margin, decreases, by which an error may occur. Therefore, it may be necessary to control the reference voltage V_{ref} in conformity with the characteristic of the input signal DIN and secure a maximum data margin within the limited cycle of the input signal DIN.

At the time t7, the code generator 200 included in the data pin reference voltage generation circuit 10 receives the voltage difference VDRF stored in the charge storage unit 120a or 120b, by complementarily responding to the amplification enable signal AMPEN. In (i) of FIG. 4, a value decreased to be smaller than the charge storing initial value is received.

While it is illustrated for the sake of convenience in explanation that the latched output signal LDIN and the data strobe signal DQS are provided in (i) of FIG. 4 corresponding to the period in which the training operation is performed, since the latched output signal LDIN may be generated in response to the enable signal EN, the latched output signal LDIN may not be generated during the training operation in which the amplification enable signal AMPEN is enabled. Similarly, the data strobe signal DQS may also not be provided during the training operation. However, according to an embodiment, because the data pin reference voltage generation circuit 10 illustrated in FIG. 1 may operate for each data pin and thus a normal operation may be performed for another data pin while the training operation is performed for a data pin, the data strobe signal DQS may be provided regardless of the training operation.

The code generator 200 may generate the voltage generation code CD according to the stored voltage difference VDFR received at the time t7, and the reference voltage generator 300 may generate the reference voltage V_{ref} through updating.

Unlike (i) of FIG. 4, in (ii) of FIG. 4, since the reference voltage V_{ref} is positioned at the center of the input signal DIN, the period during which the latched output signal LDIN is the logic ‘high’ state and the period during which the latched output signal LDIN is the logic ‘low’ state are the same. Accordingly, it may be seen that the same data margin is secured at a time t8 and a time t9 at which the latched output signal LDIN is sampled by the data strobe signal DQS.

As a data margin is secured in this way, a data margin may be sufficiently secured regardless of which value the latched output signal LDIN has, and a possibility of data to be erroneously identified may be decreased.

As a consequence, in the data pin reference voltage generation circuit 10 according to an embodiment, by controlling the reference voltage V_{ref} for each data pin, data may be precisely determined in conformity with the characteristic of each data pin.

FIG. 5 is a circuit diagram illustrating a representation of an example of the input buffer included in the data pin reference voltage generation circuit of FIG. 1.

Referring to FIG. 5, the input buffer 400 may include first and second PMOS transistors MP0 and MP1. The input buffer 400 may include first to third NMOS transistors MN0, MN1 and MN2. The input buffer 400 may include a buffer BF.

The first PMOS transistor MP0 may include a first terminal coupled with the power supply voltage VDD and a second terminal coupled with a gate terminal. The second PMOS transistor MP1 may include a first terminal coupled with the power supply voltage VDD. The second PMOS transistor MP1 may include a gate terminal coupled with the gate terminal of the first PMOS transistor MP0. The second PMOS transistor MP1 may include a second terminal coupled with the input terminal of the buffer BF.

The first NMOS transistor MN0 may include a first terminal coupled with the second terminal of the third NMOS transistor MN2. The first NMOS transistor MN0 may include a gate terminal configured for receiving the input signal DIN. The first NMOS transistor MN0 may include a second terminal coupled with the second terminal of the first PMOS transistor MP0. The second NMOS transistor MN1 may include a first terminal coupled with the second terminal of the third NMOS transistor MN2. The second NMOS transistor MN1 may include a gate terminal configured for receiving the reference voltage V_{ref}. The second NMOS transistor MN1 may include a second terminal coupled with the input terminal of the buffer BF. The third NMOS transistor MN2 may include a first terminal coupled with the ground voltage GND. The third NMOS transistor MN2 may include a gate terminal configured for receiving the enable signal EN. The third NMOS transistor MN2 may include a second terminal commonly coupled with the first terminal of the first NMOS transistor MN0 and the first terminal of the second NMOS transistor MN1.

The first PMOS transistor MP0, the second PMOS transistor MP1, and the first to third NMOS transistors MN0, MN1 and MN2 may correspond to a differential amplifier for starting an operation in response to the enable signal EN, amplifying the difference between the input signal DIN and the reference voltage V_{ref} and providing the amplified difference to the input terminal of the buffer BF.

The buffer BF may provide the latched output signal LDIN to correspond to the logic ‘high’ state or the logic ‘low’ state, based on the amplified value of the difference between the input signal DIN and the reference voltage V_{ref}.

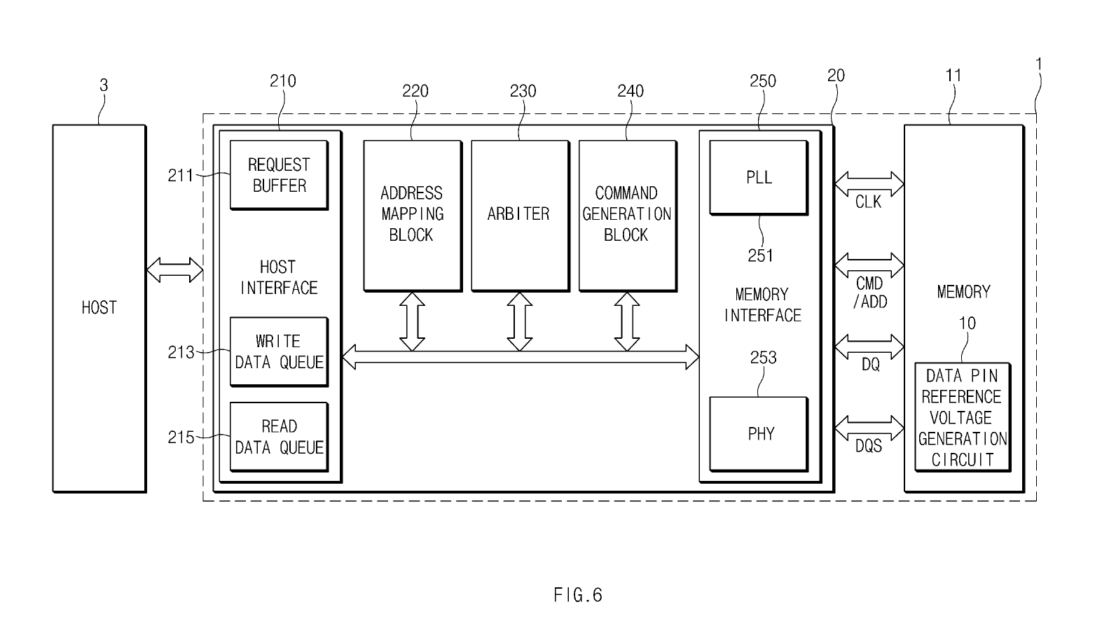

FIG. 6 is a block diagram schematically illustrating a representation of an example of the configuration of a semiconductor system in accordance with an embodiment.

Referring to FIG. 6, a semiconductor system may include a host 3 and a semiconductor device 1. The semiconductor device 1 may include a memory controller 20 and a memory 11. The data pin reference voltage generation circuit 10 described above may be included in the memory 11, and data DQ inputted to or outputted from the memory controller 20 may correspond to the above-described input signal DIN. The memory 11 may be inputted with and output data DQ from and to the memory controller 20 through a plurality of data pins PIN, and at least one data pin reference voltage generation circuit 10 may be included in the memory 11.

The host 3 may transmit a request and data to the memory controller 20 to access the memory 11. The host 3 may transmit data to the memory controller 20 to store the data in the memory 11. Also, the host 3 may receive the data outputted from the memory 11, through the memory controller 20. The memory controller 20 may provide data information, address information, memory setting information, a write request, a read request and so forth to the memory 11 in response to a request, and control the memory 11 such that a write or read operation is performed. The memory controller 20 may relay the communication between the host 3 and the memory 11. The memory controller 20 may receive a request and data from the host 3, and, in order to control the operation of the memory 11, may generate and provide to the memory 11 data DQ, a data strobe DQS, a command CMD, a memory address signal ADD, a clock signal CLK and so forth. Moreover, the memory controller 20 may provide data DQ and a data strobe DQS outputted from the memory 11, to the host 3.

In FIG. 6, the memory controller 20 may include a host interface 210, an address mapping block 220, an arbiter 230, a command generation block 240, and a memory interface 250.

The host interface 210 may include a request buffer 211, a write data queue 213, and a read data queue 215.

The memory interface 250 may be provided as an interface between the memory controller 20 and the memory 11. The memory interface 250 may include a phase-locked loop (PLL) 251 and a physical layer (PHY) 253.

While component elements constructing the memory controller 20 are illustrated as an example, it is to be noted that the embodiments are not limited to such an example and other component elements may be added according to the function of the memory controller 20. The request buffer 211 may receive the request inputted from the host 3. The write data queue 213 may receive the data inputted from the host 3, and the read data queue 215 may receive the data outputted from the memory 11. The address mapping block 220 may generate a memory address signal from the physical address signal of the request received through the request buffer 211. The arbiter 230 may provide the memory address signal and the data received through the write data queue 213, to the memory interface 250, and may provide the data DQ outputted from the memory 11, to the read data queue 215. The arbiter 230 may efficiently control the write data queue 213 or the read data queue 215 based on data traffic. The arbiter 230 may rearrange the order of the plurality of requests received from the host 3, in consideration of the operational efficiency of the memory 11. The command generation block 240 may generate commands from the write request and the read request received from the request buffer 211 and may provide the generated commands to the memory 11 such that the memory 11 may perform a plurality of operations including write, read and refresh.

The memory controller 20 in accordance with an embodiment may provide a training waveform as the input signal DIN through at least one data pin PIN included in the data pin reference voltage generation circuit 10 disposed in the memory 11, along with the amplification enable signal AMPEN.

For example, the memory controller 20 may generate a training waveform as a waveform of which integral sum for a preset time based on the reference voltage V_{ref} is ‘0’.

A training operation is performed as the memory controller 20 enables the amplification enable signal AMPEN. As described above, the memory controller 20 may train the reference voltage V_{ref} for at least one data pin PIN by providing the training waveform while enabling the amplification enable signal AMPEN for the preset time. After the training is completed, the memory controller 20 provides data DQ as the input signal DIN through at least one data pin PIN while enabling the enable signal EN.

The memory controller 20 may generate the switching control signal SWCON for controlling the plurality of switches included in the charge storage unit 120a or 120b, and provide the generated switching control signal SWCON to the data pin reference voltage generation circuit 10.

For example, in the example where the data pin reference voltage generation circuit 10 includes the voltage difference storage block 100a as illustrated in FIG. 2, the memory controller 20 generates the switching control signal SWCON such that the voltage difference storage block 100a operates as described below.

In order to ensure that the voltage difference storage block 100a may be initialized before the training operation is performed, the first and second switches SW1 and SW2 are turned off and the third and fourth switches SW3 and SW4 are turned on such that all the charges stored in the first capacitor C1 are discharged to the ground voltage GND and the power supply voltage VDD is stored in the second capacitor C2.

Then, also before the training operation is performed, the first and second switches SW1 and SW2 are turned on and the third and fourth switches SW3 and SW4 are turned off such that a charge sharing initial value may be uniformly stored in the first capacitor C1 and the second capacitor C2.

Thereafter, during the training operation, the memory controller 20 may cut off the coupling between the first capacitor C1 and the second capacitor C2 of FIG. 2 in response to the amplification enable signal AMPEN, and generate the switching control signal SWCON to couple the amplifier 110 and the first capacitor C1.

In an embodiment, in the example where the data pin reference voltage generation circuit 10 includes the voltage difference storage block 100b as illustrated in FIG. 3, the memory controller 20 generates the switching control signal SWCON such that the voltage difference storage block 100b operates as described below.

Before the training operation is performed, the fifth switch SW5 is turned off and the sixth switch SW6 is turned on such that a charge storing initial value corresponding to ½ of the power supply voltage VDD is stored in the third capacitor C3. Thereafter, during the training operation, the fifth switch SW5 is turned on and the sixth switch SW6 is turned off such that the voltage difference provided from the amplifier 110 is stored in the third capacitor C3.

While the host 3 and the memory controller 20 are illustrated in FIG. 6 as physically separated component elements, the memory controller 20 may be included (embedded) in a processor of the host 3, such as a central processing unit CPU, an application processor (AP) and a graphic processing unit (GPU), or may be realized along with these processors as one chip in the form of an SoC (system-on-chip).

The physical layer 253 may couple the memory controller 20 and the memory 11 with each other. The PLL 251 may generate a system clock signal to be used in the memory controller 20. The memory controller 20 may transmit a signal for controlling the operation of the memory 11, to the memory 11 in synchronization with the system clock signal. The physical layer 253 may convert the signal generated in the memory controller 20 in synchronization with the system clock signal, into a signal suitable for being used in the memory 11, or, conversely, may convert the signal outputted from the memory 11, into a signal suitable for being used in the memory controller 20. In addition, the physical layer 253 may generate a clock signal CLK from the system clock signal and transmit the generated clock signal CLK to the memory 11.

The memory 11 includes at least one data pin reference voltage generation circuit 10. The memory 11 may receive the memory setting information, the command CMD, the memory address signal ADD, the data DQ, the data strobe DQS and the clock CLK through the memory interface 250 from the memory controller 20, and may perform a data reception operation based on the signals.

The memory 11 may include a plurality of memory banks, and may store the data DQ in a certain region among the memory banks based on the memory address signal ADD. In the memory 11 in accordance with an embodiment, in order to secure a data margin, the reference voltage V_{ref} is controlled for each data pin, whereby it may be possible to improve the reliability of data to be stored in a memory bank.

Also, the memory 11 may perform a data transmission operation based on the command CMD, the memory address signal ADD and the data strobe DQS received from the memory controller 20. The memory 11 may transmit the data stored in a certain region among the memory banks, to the memory controller 20, based on the memory address signal ADD, the data DQ and the data strobe DQS. While it was described above as an example that the data pin reference voltage generation circuit 10 controls the reference voltage V_{ref} to identify the value of the data DQ, it is to be noted that an embodiment is not limited to such an example and the data pin reference voltage generation circuit 10 may be provided for each of the pins which receive the command CMD or the memory address signal ADD.

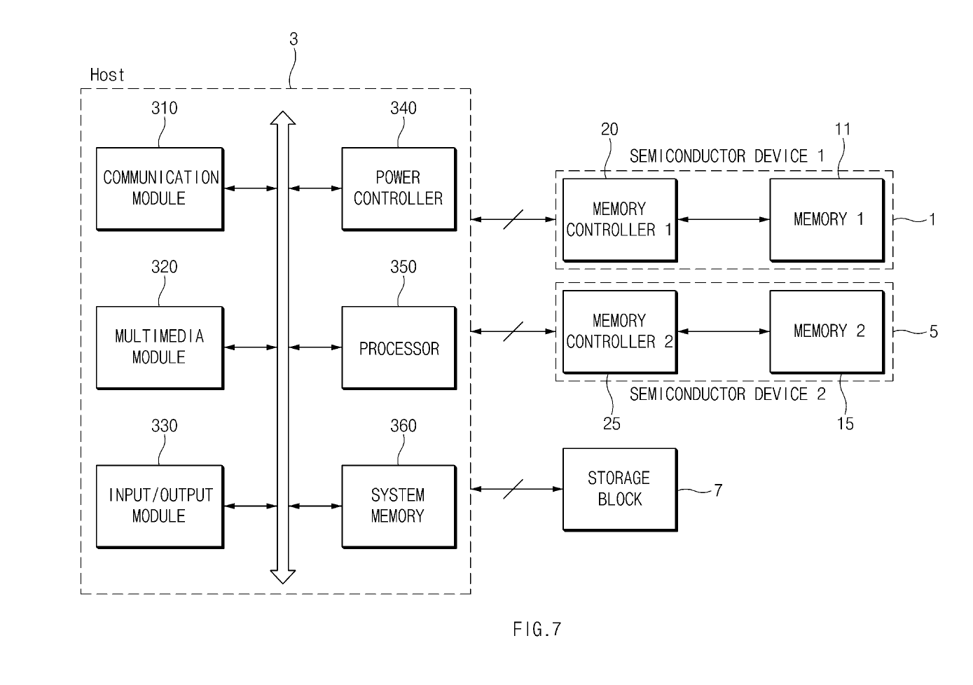

FIG. 7 is a block diagram illustrating a representation of an example of the configuration of an electronic device in accordance with an embodiment.

An electronic device may mean a computing device or system capable of executing computer-readable commands. Examples of the electronic device may include, but are not limited to, workstations, laptops, client-side terminals, servers, distributed computing systems, handheld devices, and video game consoles.

As illustrated in FIG. 7, the electronic device may include a host 3, a first semiconductor device 1, and a second semiconductor device 5. The host 3 may include modules capable of performing various functions, such as, for example but not limited to, a processor 350, a system memory 360, a power controller 340, a communication module 310, a multimedia module 320 and an input/output module 330. The host 3 may include a system bus for coupling the respective modules with one another.

The processor 350 may execute an operating system in the electronic device, perform various calculating functions, and control the system memory 360, the power controller 340, the communication module 310, the multimedia module 320 and the input/output module 330 included in the host 3, the first semiconductor device 1, the second semiconductor device 5, and a storage block 7. The processor 350 may include a central processing unit (CPU), a graphic processing unit (GPU), a multimedia processor (MMP) or a digital signal processor (DSP). The processor 350 may be realized in the form of an SoC (system-on-chip) by combining processor chips having various functions such as application processors (AP).

The system memory 360 may store information on the system, archive the data processed by the processor 350, and store the data generated as a result of calculation by the processor 350.

The power controller 340 may control a power supply amount such that power appropriate for the processor 350 and the respective component elements in the electronic device to operate and function is supplied. Such a power controller 340 may include a PMIC (power management IC). The power controller 340 may be supplied with power from an exterior of the electronic device, or may be supplied with power from a battery (not illustrated) in the electronic device.

The communication module 310 may perform signal transmission and reception between the processor 350 and devices outside the electronic device according to various communication protocols. The communication module 310 may include a module capable of being coupled with a wired network and a module capable of being coupled with a wireless network. The wired network module may perform signal transmission and reception in a communication scheme such as the Local Area Network (LAN), the Ethernet and the Power Line Communication (PLC). The wireless network module may perform signal transmission and reception in a communication scheme such as the Bluetooth, the RFID (Radio Frequency Identification), the Long Term Evolution (LTE), the Wireless Broadband Internet (Wibro) and the Wideband CDMA (WCDMA).

The multimedia module 320 may perform calculation or input/output of multimedia data according to the control of the processor 350. The multimedia module 320 may be inputted with and output multimedia data by being coupled with a camera device, an audio device, a 2D or 3D graphic device, a display device, an A/V output device, etc.

The input/output module 330 may be inputted with a signal and output a certain signal to a user, through a user interface. The input/output module 330 may be inputted with a signal by being coupled with a keyboard, a keypad, a mouse, a stylus, a microphone, a resistive type touch screen device, a capacitive type touch screen device, etc., and may output a signal through a speaker, an ear phone, a printer, a display device, etc.

The first semiconductor device 1 may store the data received from the host 3 or output stored data to the host 3, according to the control of the processor 350 included in the host 3. The first semiconductor device 1 may include at least one first memory controller 20 and at least one first memory 11. The first memory controller 20 included in the first semiconductor device 1 may correspond to the memory controller 20 described above with reference to FIG. 6, and the first memory 11 may correspond to the memory 11 described above with reference to FIG. 6 and include at least one data pin reference voltage generation circuit 10.

The first memory controller 20 may transmit information or signals such as a clock (CLK), a command/address (CA), a data strobe signal (DQS), data (DATA) and so forth to the first memory 11 as the occasion demands, according to the control of the processor 350 included in the host 3, to control the data input/output operations of the first memory 11. Such information or signals may be transmitted through the same channel or different channels.

The first memory 11 may be inputted with and output an input signal (DIN) in response to the clock (CLK), the command/address (CA), the data strobe signal (DQS) and so forth applied from the first memory controller 20. Such a first memory 11 may be realized by a volatile memory device such as an SRAM (static RAM), a DRAM (dynamic RAM) and an SDRAM (synchronous DRAM). The first memory 11 may include the data pin reference voltage generation circuit 10 described above with reference to FIGS. 1 to 6.

The second semiconductor device 5 may operate or function as a memory system which may quickly indentify a received control signal and start an operation corresponding to the received control signal. The second semiconductor device 5 may include at least one second memory controller 25 and at least one second memory 15.

The second memory controller 25 may be coupled with the second memory 15 through one or more channels. The second memory controller 25 may control the read, program and erase operations of the second memory 15 according to the control of the processor 350.

The second memory 15 may be coupled with the second memory controller 25 through a plurality of channels. The second memory 15 may include at least one among nonvolatile memory devices such as a ROM (read only memory), a PROM (programmable ROM), an EEPROM (electrically erasable and programmable ROM), an EPROM (electrically programmable ROM), a flash memory, a PRAM (phase change RAM), an MRAM (magnetic RAM), an RRAM (resistive RAM) and an FRAM (ferroelectric RAM). One or more nonvolatile memory devices may be coupled to one channel. The nonvolatile memory devices coupled to one channel may be coupled to the same control signal bus and data bus.

The electronic device may include the storage block 7 for storing large capacity data, or may use a storage block outside the electronic device. The storage block 7 may be a large capacity data storage device for storing data and commands for the various component elements of the electronic device. The storage block 7 may be realized by a device such as at least one HDD and a flash-based SSD.

It is to be noted that the respective component elements illustrated in FIG. 7 are classified functionally and are not necessarily classified physically. For example, two or more component elements among the component elements of FIG. 7 may be formed in one physical semiconductor chip or may be included in a single package.

As described above, in the data pin reference voltage generation circuit 10 and the semiconductor device 1 including the same in accordance with the embodiments, since the reference voltage V_{ref} is generated through updating, for each data pin, based on a value acquired by accumulatively storing the difference between the input signal DIN and the reference voltage V_{ref} in the training operation, it may be possible to reflect the characteristic of the input signal DIN that is different from data pin to data pin.

Accordingly, because the data margin of the input signal DIN provided through the data pin PIN may be secured, it may be possible to precisely identify a data value.

While various embodiments have been described above, it will be understood to those skilled in the art that the embodiments described are by way of example only. Accordingly, the data pin reference voltage generation circuit and the semiconductor device including the same described herein should not be limited based on the described embodiments.

1. A data pin reference voltage generation circuit comprising:
a voltage difference integrator configured to integrate a voltage difference between an input signal received through a data pin and a reference voltage for a preset time;
a code generator configured to generate a voltage generation code based on a value integrated by the voltage difference integrator; and
a reference voltage generator configured to update the reference voltage based on the voltage generation code.

2. The data pin reference voltage generation circuit according to claim 1, wherein the voltage difference integrator comprises:
an amplifier configured to amplify the voltage difference between the input signal and the reference voltage in response to an amplification enable signal, and provide the amplified voltage difference; and
a charge storage unit configured to store charges to integrate the provided voltage difference.

3. The data pin reference voltage generation circuit according to claim 2, wherein the code generator is provided with charges stored in the charge storage unit by complementarily responding to the amplification enable signal.

4. The data pin reference voltage generation circuit according to claim 2, wherein the charge storage unit comprises:
an initialization section configured to provide a charge storing initial value to a capacitor included in the charge storage unit.

5. The data pin reference voltage generation circuit according to claim 4, wherein the initialization section comprises:
an auxiliary capacitor configured to set the capacitor to the charge storing initial value by sharing charges with the capacitor in response to a switching control signal while storing a power supply voltage.

6. The data pin reference voltage generation circuit according to claim 4, wherein the charge storing initial value corresponds to a ½ value of the power supply voltage.

7. The data pin reference voltage generation circuit according to claim 5, wherein the charge storing initial value corresponds to a ½ value of the power supply voltage.

8. The data pin reference voltage generation circuit according to claim 5, wherein the capacitor and the auxiliary capacitor have substantially the same capacitance.

9. The data pin reference voltage generation circuit according to claim 2, further comprising:
an input buffer configured to amplify a voltage difference between an updated reference voltage and the input signal received through the data pin, in response to an enable signal, and provide a latched output signal.

10. A semiconductor device comprising:
a memory controller configured to provide a training waveform through at least one data pin, along with an amplification enable signal; and
at least one data pin reference voltage generation circuit configured to integrate a voltage difference between the training waveform and a reference voltage in response to the amplification enable signal, and update the reference voltage.

11. The semiconductor device according to claim 10, wherein the memory controller trains the reference voltage for the at least one data pin by providing the training waveform while enabling the amplification enable signal for a preset time, and provides a data input signal through the at least one data pin while enabling an enable signal after training is completed.

12. The semiconductor device according to claim 11, wherein the training waveform is a waveform of which integral sum based on an updated reference voltage is ‘0’.

13. The semiconductor device according to claim 11, wherein the data pin reference voltage generation circuit comprises:
a voltage difference integrator configured to integrate the voltage difference between the training waveform and the reference voltage for the preset time in response to the amplification enable signal;
a code generator configured to generate a voltage generation code based on a value integrated by the voltage difference integrator; and
a reference voltage generator configured to update the reference voltage based on the voltage generation code.

14. The semiconductor device according to claim 13, wherein the voltage difference integrator comprises:
an amplifier configured to amplify the voltage difference between the training waveform and the reference voltage in response to the amplification enable signal, and provide the amplified voltage difference; and
a charge storage unit configured to store charges obtained by integrating the provided voltage difference.

15. The semiconductor device according to claim 14, wherein the code generator is provided with the charges stored in the charge storage unit by complementarily responding to the amplification enable signal.

16. The semiconductor device according to claim 14, wherein the charge storage unit comprises:
an initialization section configured to provide a charge storing initial value to a capacitor included in the charge storage unit.

17. The semiconductor device according to claim 16, wherein the initialization section comprises:
an auxiliary capacitor configured to set the capacitor to the charge storing initial value by sharing charges with the capacitor in response to a switching control signal while storing a power supply voltage.

18. The semiconductor device according to claim 17, wherein the memory controller generates the switching control signal which cuts off coupling between the capacitor and the auxiliary capacitor and couples the amplifier and the capacitor, in response to the amplification enable signal.

19. The semiconductor device according to claim 17, wherein the capacitor and the auxiliary capacitor have the same capacitance.

20. The semiconductor device according to claim 16, wherein the initialization section includes a voltage source which provides the charge storing initial value, and the memory controller generates the switching control signal which couples the voltage source and the capacitor and retains the capacitor at the charge storing initial value, and cuts off coupling between the voltage source and the capacitor and couples the amplifier and the capacitor in response to the amplification enable signal.
